(19) United States
(12) Patent Application Publication
(10) Pub. No.: US 2008/0250847 A1
(43) Pub. Date: Oct. 16, 2008

(54) DETECTOR AND PRODUCTION METHOD THEREOF

(75) Inventors: Tomoyuki KITANI, Yokohama-shi (JP); Miyuki Takenaka, Yokohama-shi (JP); Mitsuhiro Oki, Yokohama-shi (JP); Masami Okamura, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignees: KABUSHIKI KAISHA TOSHIBA, Tokyo (JP); TOSHIBA MATERIALS CO., LTD., Yokohama-shi (JP)

(21) Appl. No.: 12/061,966

(22) Filed: Apr. 3, 2008

(30) Foreign Application Priority Data
Apr. 10, 2007 (JP) 2007-103176

(51) Int. Cl. G01N 7/00; G01R 31/28

(52) U.S. Cl. 73/31.05; 29/593

(57) ABSTRACT

A detector for detecting a gaseous component in a gas is comprised of a sensor having a gas detecting region configured to output an electric signal in response to detection of the gaseous component and a contact portion configured to conduct the electric signal; an enclosure housing the sensor and having a through hole configured to introduce the gas to the gas detecting region; a wiring partly facing to the contact portion and being led out of the enclosure; an electric conductor interposed between the contact portion and the wiring; a packing member surrounding the through hole and so as to make a gap between the sensor and the enclosure impervious to the gas.

### CROSS-REFERENCE TO RELATED APPLICATIONS

This application is based upon and claims the benefit of priority from the prior Japanese Patent Application No. 2007-103176 (filed Apr. 10, 2007); the entire contents of which are incorporated herein by reference.

### BACKGROUND OF THE INVENTION

1. Field of the Invention

The present invention relates to a detector for detecting gaseous components contained in any gas, such as oxygen and any nitrides contained in exhaust gas from vehicles, and a production method thereof.

2. Description of the Related Art

Gas sensors are used to detect gaseous components contained in various gases. A gas sensor is often housed in a proper enclosure and a plurality of electric contacts are made therein so as to conduct electric signals out of the enclosure. Japanese Patent Applications Laid-open No. 2002-174608 and No. 2002-189011 disclose related arts.

The gas sensors are often used in high-temperature atmospheres including corrosive gaseous components, such as exhaust gas from a vehicle. Then both the high temperature and the corrosive gaseous components may give rise to contact failure and its possibility considerably increases over time.

### SUMMARY OF THE INVENTION

Certain embodiments provide a detector for detecting a gaseous component applicable to long-term use in high-temperature corrosive atmospheres.

According to an aspect of the present invention, a detector for detecting a gaseous component in a gas is comprised of a sensor having a gas detecting region configured to output an electric signal in response to detection of the gaseous component and a contact portion configured to conduct the electric signal; an enclosure housing the sensor and having a through hole configured to introduce the gas to the gas detecting region; a wiring partly facing to the contact portion and being led out of the enclosure; an electric conductor interposed between the contact portion and the wiring; and a packing member surrounding the through hole so as to make a gap between the sensor and the enclosure impervious to the gas.

According to another aspect of the present invention, a method for producing a detector from a sensor having a gas detecting region and a contact portion and an enclosure having a main body and a lid portion put on the main body, a through hole and a wiring, is comprised of printing first raw material of an electric conductor so as to interpose the first raw material between the contact portion and the wiring, and second raw material of a packing member so as to have the second raw material surround the through hole, respectively on the enclosure; executing flip chip bonding so as to establish contact between the contact portion and the first raw material and dispose the gas detecting region to be surrounded with the packing member; curing the first raw material and the second raw material by heating; applying third raw material of a bond on the main body so as to interpose the third raw material between the main body and the lid portion; and curing the third raw material by heating.

### BRIEF DESCRIPTION OF THE DRAWINGS

FIG. 1 is a perspective view of a detector in accordance with an embodiment of the present invention;

FIG. 2 is a cross sectional view of the detector taken from a II-II line of FIG. 1;

FIG. 3 is a bottom view of the detector;

FIG. 4 is a plan view of the detector from which a lid portion is removed;

FIGS. 5A through 5D are drawings illustrative of production steps of the detector; and

FIG. 6 is an elevational view of a detector in accordance with a modified embodiment of the present invention.

### DETAILED DESCRIPTION OF THE INVENTION

Exemplary embodiments of the present invention will be described hereinafter with reference to the appended drawings. Meanwhile, illustrations of a detector in these drawings are no more than schematic drawings and therefore the elements shown in the drawings are not necessarily drawn to scale. Shapes, dimensions, proportions and arrangement of elements in practical products may be allowed to differ from those in the illustrations.

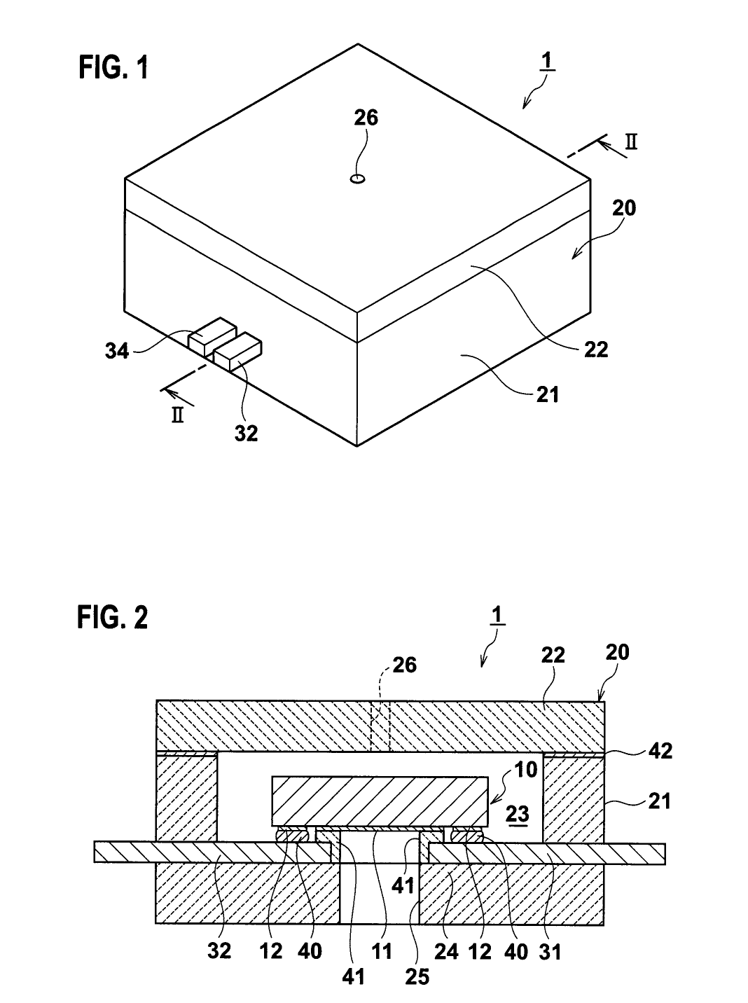

As shown in FIG. 1, a detector 1 in accordance with an embodiment of the present invention has a box-like outline with a wiring led out thereof. The outline may be, but not limited to, a rectangular parallelepiped shape. The wiring includes a plurality of lead lines 31-34, each formed in a planar bar shape or a film-like shape. The number of the lead lines is not limited to four.

Referring to FIG. 2, the detector 1 is comprised of a semiconductor sensor 10 for detecting a gaseous component, and an enclosure 20 housing the sensor 10.

The semiconductor sensor 10 is comprised of a gas detecting region 11, which outputs electric signals in response to detection of the gaseous component, and a contact portion 12 including a plurality of electric contacts for conducting the electric signal out of the sensor 10. The gas detecting region 11 is formed substantially at a center of a main face (drawn as a lower face in the drawing) and the contact portion 12 is also formed on the main face around the gas detecting region 11. The electric contacts of the contact portion 12 are arranged in two lines on both sides of, or around, the gas detecting region 11. Alternatively, any other arrangement may be applicable.

The semiconductor sensor 10 is formed from a bulk of single-crystal silicon and is further comprised of components respectively made of any semiconductor materials, examples of which may be silicon, glass of silicon dioxide, sintered ceramic of aluminum nitride or such. Linear expansivities thereof are sufficiently close together and typically have a value of 7.7×10⁻⁶/° C. Of course, constituent materials of the semiconductor sensor 10 are not limited to them.

The enclosure 20 is comprised of a main body 21 and a lid portion 22 to be put on the main body 21. The enclosure 20 has an interior cavity 23, as defined by the main body 21 and the lid portion 22, for housing the semiconductor sensor 10.

The enclosure 20 is made of a material having a linear expansivity close to those of the materials of the semiconductor sensor 10. Ceramic of alumina, a chemical formula of which is described as Al₂O₃, of 90% purity may be applicable, but not limited to, the material of the enclosure 20. The alumina ceramic has a linear expansivity of 7.2×10⁻⁶/° C.

Respective interior portions of the lead lines 31-34 are placed on a bottom face of the interior cavity 23. Respective two of the lead lines 31-34 are placed at both sides in the interior cavity 23, as corresponding to the arrangement of the electric contacts of the semiconductor sensor 10, so that the interior portions of the lead lines 31-34 respectively face the electric contacts of the contact portion 12 of the semiconductor sensor 10.

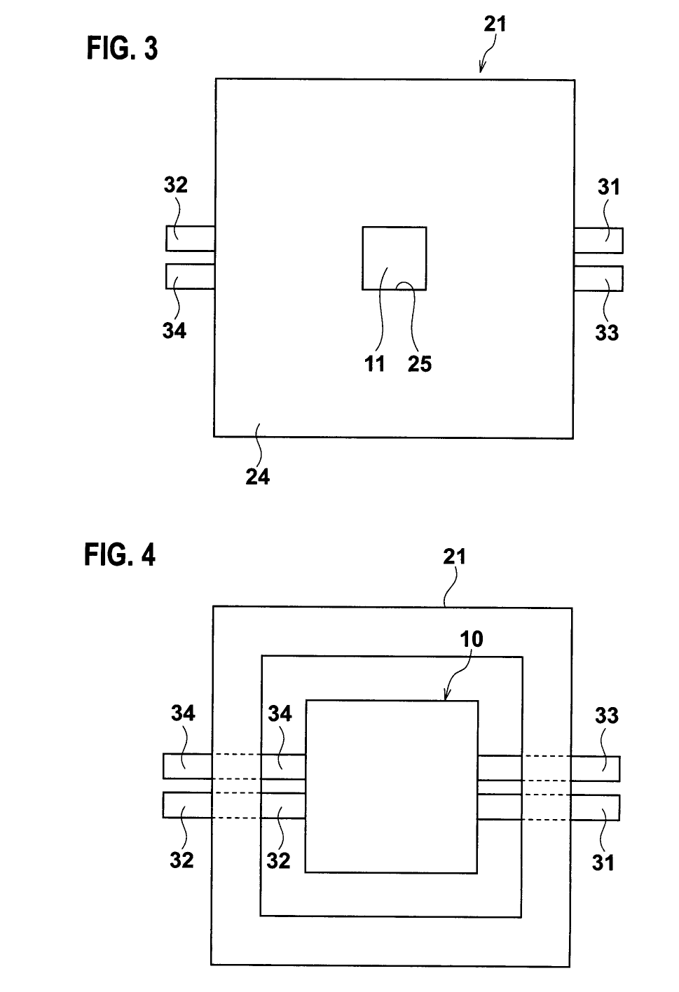

Referring to FIG. 3, a bottom plate 24 of the main body 21 has a through hole 25 so dimensioned as to align with the gas detecting region 11 to introduce gas to the gas detecting region 11. Alternatively, any equivalent which allows passage of gas, such as a porous body, a filter, a honeycomb or plural through holes, may be provided instead of the through hole 25.

The lid portion 22 is a rectangular plate having an opening 26 which allows gas passage therethrough, as shown in FIGS. 1 and 2. The opening 26 is capable of gas passage therethrough and internal pressure relief thereby when heating and cooling the enclosure 20 causes change in internal pressure thereof. As with the through hole 25, the opening 26 may be also replaced with any equivalent which allows passage of gas.

Referring again to FIG. 2, electric conductors 40 are respectively interposed between the electric contacts of the contact portion 12 and the lead lines 31-34 of the wiring so as to establish electric connection therebetween. The electric conductors 40 are formed by printing water glass with aluminum (Al) powder dispersed therein and curing it by application of heat as will be described later. A linear expansivity of the cured electric conductors 40 is properly controlled so as to sufficiently close to those of the materials of the semiconductor sensor 10 and the enclosure 20 by regulating the mixing ratio of the aluminum powder to the water glass.

Water glass is well-known concentrated aqueous solution of sodium silicate produced by reaction of silicon dioxide (SiO₂) with sodium hydroxide (NaOH). Aluminum powder functions as a medium of electric conduction in the cured electric conductors 40.

In some situations, some of the lead lines 31-34 of the wiring may not contribute to conduction of the electric signals. Then gaps between the correspondent lead lines and the electric contacts may be filled with members of any electrically nonconductive material instead of the electric conductors 40. The nonconductive material may be equivalent to that constituting a packing member 41 described later.

A packing member 41 is placed on the bottom face of the interior cavity 23 of the enclosure 20 so as to surround the through hole 25 without leaving any passages therein. The packing member 41 air-tightly adhesively fills the gap between the semiconductor sensor 10 and the enclosure 20 so that the semiconductor sensor 10 securely adheres to the main body 21 and the gap therebetween is made impervious to gas. The lead lines 31-34, the electric contacts of the contact portion 12 and the electric conductors 40 are thereby cut off from the atmosphere around the through hole 25.

The packing member 41 is made of an electrically nonconductive material formed from water glass with alumina (Al₂O₃) powder dispersed therein and curing it by heating, which has a linear expansivity sufficiently close to those of the materials of the semiconductor sensor 10, the enclosure 20 and the electric conductors 40.

The main body 21 and the lid portion 22 of the enclosure 20 are joined together with thermosetting bond 42. The bond 42 is formed from water glass with alumina (Al₂O₃) powder dispersed therein and curing it by heating, as with the packing member 41, and therefore has a linear expansivity sufficiently close to those of the main body 21 and the lid portion 22.

The main body 21 and the lid portion 22 of the enclosure 20, the packing member 41, and the bond 42 may be alternatively formed from any one or more of glass mainly made of silicon dioxide (SiO₂), sintered ceramic of aluminum nitride (AlN), silicon (Si), nickel (Ni), titanium (Ti), tungsten (W), platinum (Pt), copper (Cu), silver (Ag), aluminum (Al), iron (Fe), silica (SiO₂), carbon (C), kovar (a well-known Co—Ni—Fe alloy), alumina (Al₂O₃), zirconia (ZrO₂), and magnesia (MgO), as linear expansivities of these materials are sufficiently close to that of the semiconductor sensor 10.

The electric conductors 40 may be alternatively formed from any of glass mainly made of silicon dioxide and aluminum nitride including any powder of nickel, titanium, tungsten, kovar, platinum, copper, silver, aluminum, iron, zirconia, magnesia, silica and carbon dispersed therein, as linear expansivities of these materials are sufficiently close to that of the semiconductor sensor 10.

When the detector 1 is exposed to objective gas, such as exhaust gas from a vehicle, the exhaust gas is introduced through the through hole 25 into the enclosure 20 and comes into contact with the gas detecting region 11. As the exhaust gas generally has high temperatures, the main body 21 of the enclosure 20 is heated to thermally expand. Differences in thermal expansions among related members generate shearing force around contacts among the related members. If the shearing force is sufficiently large, any of the contacts becomes broken. However, as the linear expansivities of the related materials are sufficiently close together, contacts among the semiconductor sensor 10, the enclosure 20, the electric conductors 40 and the packing member 41 are prevented from breaking as long as the temperatures thereof are within an operating temperature range of the semiconductor sensor 10. Reliable operation of the detector 1 can be ensured within the operation temperature range of the semiconductor sensor 10.

The air-tightly filled packing member 41 prevents the exhaust gas from flowing through the gap between the semiconductor sensor 10 and the enclosure 20 toward the lead lines 31-34, the electric contacts of the contact portion 12 and the electric conductors 40. The lead lines 31-34, the electric contacts of the contact portion 12 and the electric conductors 40 are not exposed to the corrosive exhaust gas and therefore reliability of electric contact among them can be preserved over long periods.

Internal pressure relief assured by the opening 26 further contributes to prevention of failure of the detector 1 when temperature change causes internal pressure change in the interior cavity 23.

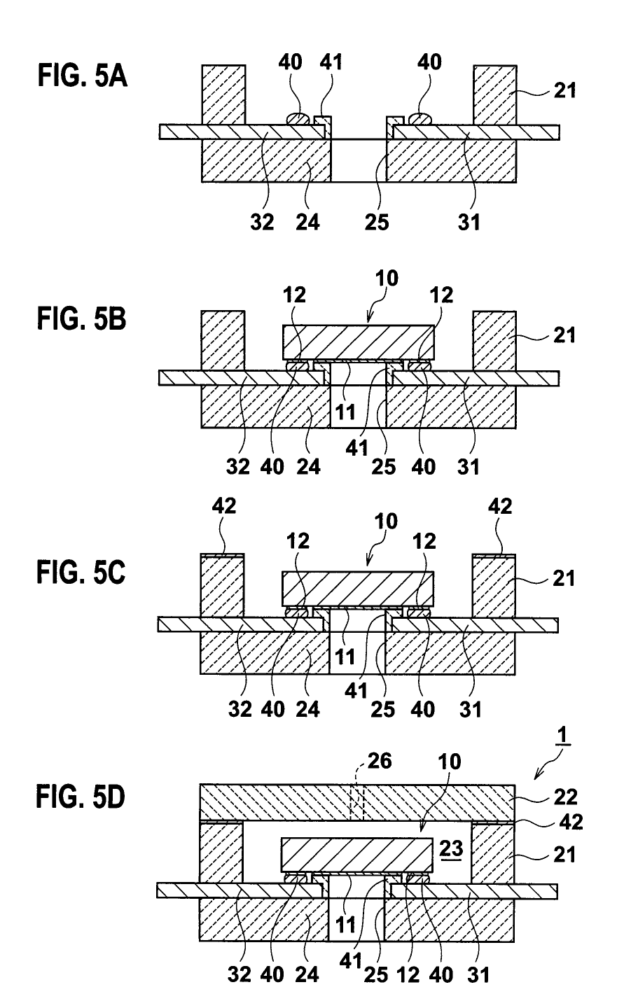

A production method in accordance with an embodiment of the present invention will be described hereinafter with reference to FIGS. 5A through 5D.

Referring to FIG. 5A, the production method includes preparing the main body 21 having the lead lines 31-34 penetrating and being led out of the main body 21, and printing raw material of the electric conductors 40 on the respective internal portions of the lead lines 31-34 placed on the enclosure 20 so that the raw material is to be interposed respectively between the electric contacts of the contact portion 12 and the lead lines 31-34 of the wiring. The printing may be carried out by means of a publicly-known printing method. The raw material is, as already described above, uncured water glass with powder of conductive material dispersed therein. Simultaneously or subsequently, printing another raw material of the packing member 41 on the enclosure 20 is executed so that the raw material surrounds the through hole 25 without leaving any passages therein. The raw material is, as already described above, uncured water glass with alumina or such powder dispersed therein.

Referring to FIG. 5B, the production method next includes flip chip bonding of the semiconductor sensor 10 onto the main body 21 of the enclosure 20 by means of a publicly-known flip chip bonder machine or such. Thereby, mounting of the semiconductor sensor 10 on the main body 21 is executed and contact between the contact portion 12 of the semiconductor sensor 10 and the raw material of the electric conductors 40 is established. As the flip chip bonding necessarily regulates relative positional relationship between the semiconductor sensor 10 and the main body 21, the gas detecting region 11 is aligned with the through hole 25 so as to face the exterior therethrough.

The production method next includes curing the printed raw materials to generate the cured electric conductors 40 and the cured packing member 41 by heating with applying a proper degree of pressure on the semiconductor sensor 10 toward the main body 21. The temperature as a result of heating should be 100 degrees C. or higher on the basis of curing temperature of water glass. If any other material is applied thereto, proper temperature range for curing the material should be selected.

Referring to FIG. 5C, the production method next includes applying raw material of the bond 42 on the top periphery of the main body 21. The raw material is, as already described above, uncured water glass with alumina powder dispersed therein. The production method subsequently includes placing the lid portion 22 on the bond 42 and the main body 21, and curing the raw material of the bond 42 to generate the cured bond 42 by heating with applying a proper degree of pressure on the lid portion 22. The temperature as a result of heating should be 100 degrees C. or higher on the basis of curing temperature of water glass. If any other material is applied thereto, proper temperature range should be selected.

As will be understood from the above description, the production method includes only the small number of steps and the well-known flip chip bonding method which provides excellent productivity can be used.

Proper modifications may occur on the basis of the above teachings. For example, the electric conductors 40 formed from glass may be replaced with bumps of gold, copper or aluminum formed by a publicly-known bump bonding method. As gold, copper and aluminum has linear expansivities considerably different from those of the semiconductor sensor 10 and the enclosure 20, contact between the bumps and the semiconductor sensor 10, or the enclosure 20, may be susceptible to breaking in the mechanical or chemical sense when heat is applied. However, as long as the structure of the detector 1 as a whole is prevented from breaking, the contact in the electrical sense would not break and therefore signal conduction can be preserved. Stability of the whole structure is sufficiently assured because of sufficient closeness of linear expansivities among the materials of the semiconductor sensor 10, the enclosures 20 and the other as described above.

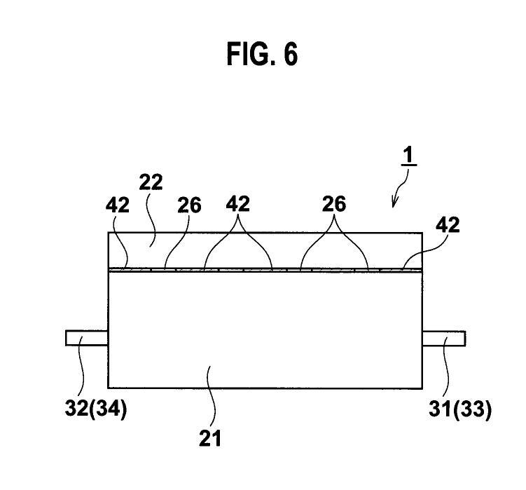

The opening 26 may be formed not on the lid portion 22 but on the main body 21. Alternatively, as shown in FIG. 6, the bond 42 may be formed discontinuously, leaving openings 26 at intervals, so as to allow internal pressure relief therethrough.

The plural conductors 40 may be formed not in such a separated manner but in an aggregative manner in which any proper nonconductive matrix links the plural conductors 40 to form in an aggregation.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A detector comprising:
a sensor having a gas detecting region configured to output an electric signal in response to detection of a gaseous component in a gas and a contact portion configured to conduct the electric signal;
an enclosure housing the sensor and having a through hole configured to introduce the gas to the gas detecting region;
a wiring partly facing to the contact portion and being led out of the enclosure;
an electric conductor interposed between the contact portion and the wiring; and
a packing member surrounding the through hole so as to make a gap between the sensor and the enclosure impervious to the gas.

2. The detector according to claim 1, wherein the sensor has an operating temperature range, and wherein the sensor, the enclosure, the electric conductor and the packing member respectively include materials having linear expansivities sufficiently close together so as not to break contacts among the sensor, the enclosure, the electric conductor and the packing member within the operating temperature.

3. The detector according to claim 1, wherein the packing member consists essentially of any electrically nonconductive material.

4. The detector according to claim 1, wherein the enclosure includes an opening configured to relieve internal pressure of the enclosure.

5. The detector according to claim 1, wherein the enclosure includes any one or more substances selected from the group of glass of silicon dioxide, ceramic of aluminum nitride, silicon, nickel, titanium, tungsten, platinum, copper, silver, aluminum, iron, silica, carbon, kovar, alumina, zirconia, and magnesia.

6. A method for producing a detector, the method comprising:
printing first raw material of an electric conductor so as to interpose the first raw material between a contact portion of a sensor and a wiring of an enclosure, and second raw material of a packing member so as to have the second raw material surround a through hole of the enclosure, respectively on the enclosure;
executing flip chip bonding so as to establish contact between the contact portion and the first raw material and dispose a gas detecting region of the sensor to be surrounded with the packing member;
curing the first raw material and the second raw material by heating;
applying third raw material of a bond on a main body of the enclosure so as to interpose the third raw material between the main body and a lid portion of the enclosure; and
curing the third raw material by heating.
